(19) United States
(12) Patent Application Publication
(10) Pub. No.: US 2013/0099263 A1
(43) Pub. Date: Apr. 25, 2013

(54) FULL SPECTRUM LED LIGHT SOURCE

(71) Applicants: Gregory Lee Heacock, Maple Valley, WA (US); Wes A. Williams, Winchester, WA (US)

(72) Inventors: Gregory Lee Heacock, Maple Valley, WA (US); Wes A. Williams, Winchester, WA (US)

(21) Appl. No.: 13/278,078

(22) Filed: Oct. 20, 2011

(51) Int. Cl. H01L 33/08

(52) U.S. Cl. 257/89; 257/98; 257/E33.06

(57) ABSTRACT

A LED light source has a red, blue and green LED triad for generating a full spectrum of colored light that appears to be emanating from a point source. The LED triad is mounted in a CPC that is surrounded by a cylindrical reflector.

### RELATED APPLICATIONS

[Not Applicable]

### FEDERALLY SPONSORED RESEARCH OR DEVELOPMENT

[Not Applicable]

### [MICROFICHE/COPYRIGHT REFERENCE]

[Not Applicable]

### TECHNICAL FIELD

The present invention relates to a LED light source suitable for illumination and displays and more particularly to a LED light source having a red, blue and green LED triad for generating a full spectrum of colored light, including white light, in which the light appears to be emanating from a point source.

### BACKGROUND OF THE INVENTION

LED light sources for generating different color wavelengths are known to include a red LED, a green LED and a blue LED wherein each of the LEDs is turned on and off rapidly and at various rates to generate various colors. The light from the LEDs is typically mixed using microsphere optics. However, if a viewer stands close enough to such a light source, the viewer can see the individual red, green and blue LEDs blinking on and off. Moreover, known LED light sources are typically not as bright as desired for viewing in daylight.

### BRIEF SUMMARY OF THE INVENTION

In accordance with the present invention, the disadvantages of prior LED full spectrum light sources have been overcome. The LED light source of the present invention utilizes optical elements to produce a full spectrum of bright colored light, including white light, from a red, green and blue LED triad where the light appears to be generated from a single source or point source.

In accordance with one embodiment of the present invention, the LED light source includes a total internal reflection compound parabolic concentrator (CPC) having a concave first surface for receiving light from an LED triad and a second surface through which light exits. The LED triad has a red LED die, a green LED die, and a blue LED die wherein the LED triad is mounted in the concave entrance surface of the CPC such that the CPC captures light emitted from the sides of the LED triad and provides a light output that is greater than or equal to 3 mW.

In another embodiment of the present invention the optics of the LED light source includes a cylindrical sleeve surrounding the CPC, the cylindrical sleeve having a reflective inner surface to reflect light escaping from the CPC back into the CPC.

In a further embodiment of the present invention, the cylindrical sleeve surrounding the CPC has a reflective inner surface that is tapered at the end of the sleeve surrounding the entrance surface of the CPC.

In another embodiment of the present invention, the center wavelength of the red LED is approximately 625 nm, the center wavelength of the green LED is approximately 535 nm and the center wavelength of the blue LED is approximately 445 nm.

In still another embodiment of the present invention, the LED triad is mounted centrally on a substrate, each of the LED has at least one wirebond on a top surface of the LED die and wherein each of the wirebonds is connected to the substrate so that it extends radially away from the center of the LED triad.

In a further embodiment, each of the LED die is connected to a heat sink trace on the substrate wherein the heat sink trace extends radially away from the center of the LED triad.

These and other advantages and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a side cross sectional view of the LED light source of one embodiment of the present invention;

FIG. 2 is a side cross sectional view of the LED light source of another embodiment of the present invention;

FIG. 3 is a perspective view of a partial cross section of the LED light source of FIG. 2; and

FIG. 4 is a top view of a substrate supporting a centrally located LED triad with outwardly radially extending wirebonds and heat sink traces.

### DETAILED DESCRIPTION OF THE INVENTION

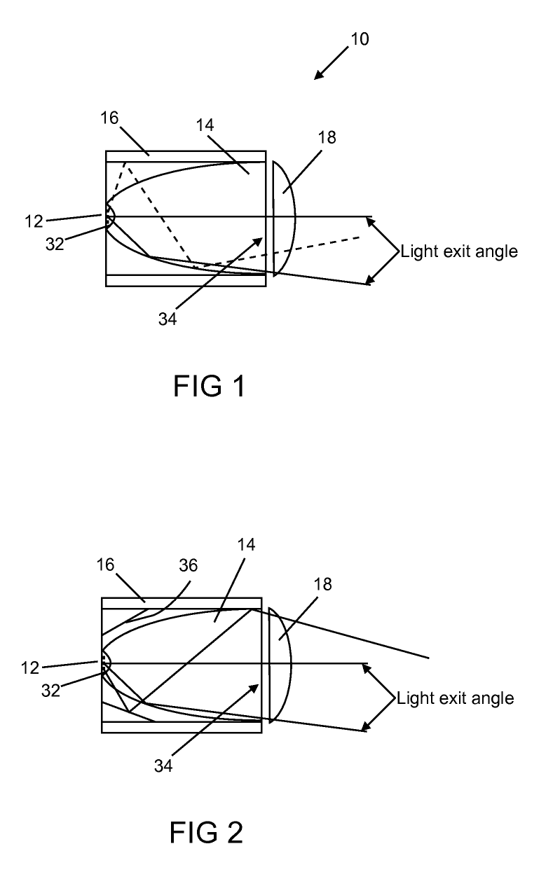

An LED light source 10 in accordance with one embodiment of the present invention, as shown in FIG. 1, includes an LED triad 12 and a multi-element optic that includes a compound parabolic concentrator (CPC) 14 and a cylindrical reflector 16. Depending upon the application of the light source 10, it may or may not include an ancillary optic 18. For example, when the light source 10 is used in large scale displays, the ancillary optic maybe a toric optic or a wedge that directs light downward towards a viewer.

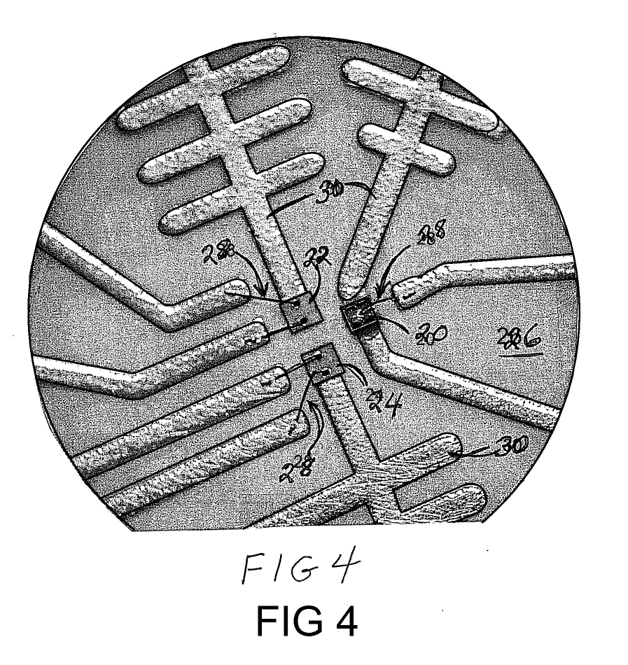

The LED triad, as shown in FIG. 4 includes a red LED die 20, a green LED die 22 and a blue LED die 24 centrally located on a substrate 26. In a preferred embodiment, the center wavelength of the red LED is approximately 625 nm, the center wavelength of the green LED is approximately 535 nm and the center wavelength of the blue LED is approximately 445 nm to match the peak absorption wavelengths of the human eye. This is opposed to standard LEDs in which the center wavelength of a red LED is 630 nm-640 nm, the center wavelength of a green LED is 520 nm-530 nm, and then center wavelength of a blue LED is 460 nm-465 nm.

Each of the LED die has one or two anodes on a top surface to which wirebonds 28 are connected. The wirebonds 28 of each of the die extend radially outward from the centrally located dice. This is opposed to the conventional arrangement where the wirebonds extend towards the center of the substrate from LED die that are located further out. It has been found that by positioning the dice 20, 22 and 24 centrally on the substrate with the wirebonds extending outwardly, any shadow in the light projecting from the LED triad assembly is minimized. The cathode of each of the LED dice 20, 22 and 24 is connected to a heat sink trace 30 to providing a passive heat removal system.

The compound parabolic concentrator (CPC) 14 is a solid optical element having a refractive index n in the range of 1.3-2.0 and preferably 1.5. The CPC 14 has a first optical surface 32 for receiving light from the LED triad 12 and a second surface 34 through which light exits the CPC. The CPC has a surface of revolution about the Z axis that is defined by the following form equations.

$$\begin{matrix}L = \frac{R \text{?} - \text{?} Sin \text{?} Cos \text{?}}{{Sin}^{2} \text{?}} & Equation 1 \\ \text{?} & Equation 2 \\ R = \frac{2 R \text{?} - \text{?} Sin \text{?} Sin \text{?} \text{?} - \text{?}}{1 - Cos \text{?}} - R \\ \text{?} \text{indicates text missing or illegible when filed} & Equation 3\end{matrix}$$

R is the radius of the small aperture 32 of the CPC 14. θₘₐₓ is the maximum acceptance angle or exit angle. [symbol] is a variable angle used to generate the CPC profile. For a small CPC that may be used in displays and lighting, R is 1.8 mm to 2.4 mm, and preferably 2.0 mm, and θₘₐₓ is 35° to 55°, and preferably 45°. Further, when the small CPC is used with a toric optic 18, light is projected in an elliptical pattern having a radiation angle of approximately 50°×100°. For a large CPC that may be used for illumination of structures or an area, R is 1.8 mm to 2.4 mm, and preferably 2.0 mm, but θₘₐₓ is 18° to 22°, and preferably 20°. For the large CPC, light is projected in a conical pattern having a radiation angle of approximately 70°.

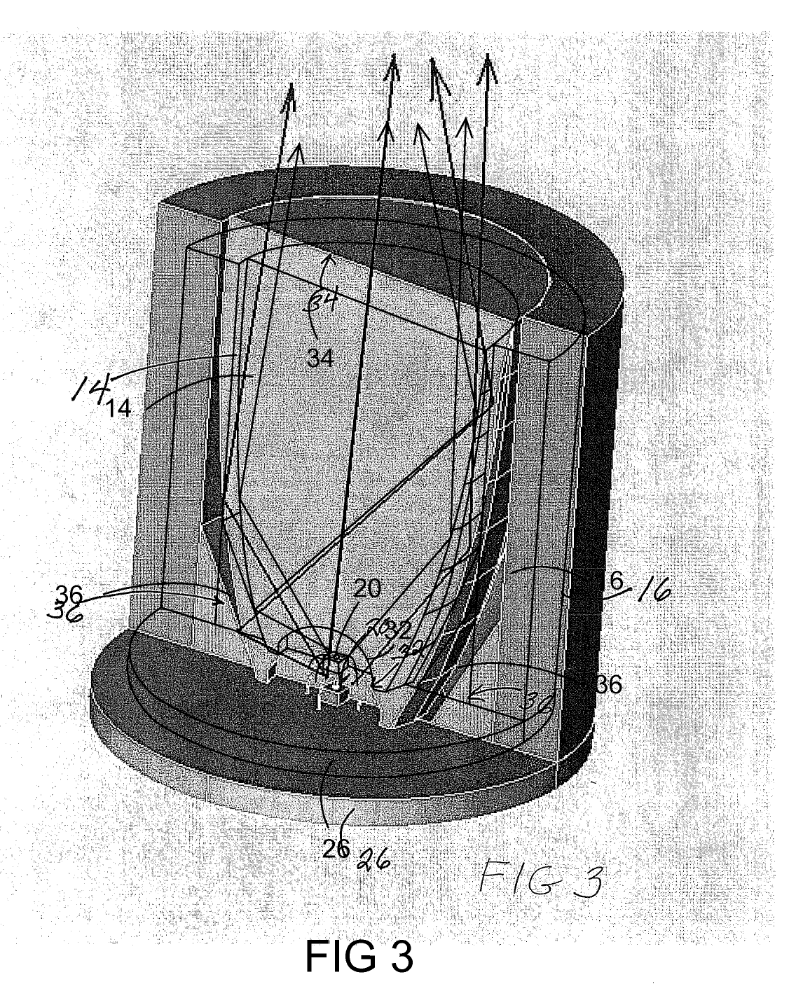

In a preferred embodiment of the present invention, the first optical surface 32 of the CPC is concave to allow the LED triad 12 to be mounted within the geometry of the CPC. More particularly, as can be seen from FIG. 3, the top surface of the substrate 26 abutting the back surface of the dice 20, 22 and 24 is coplanar to a plane that is tangent to the top most surface of the CPC. As such, the LED triad 12 is mounted in the concave entrance surface 32 of the CPC. It has been found that mounting the LED triad in a concave entrance surface 32 of the CPC allows light emitted from the side of the LED dice to be captured by the CPC 14 and/or cylindrical reflector 16. Moreover, the LED triad 12 is secured to the CPC in the concave entrance surface 32 with a silicone gel having an index of refraction that matches the index of refraction of the CPC 14 or that is between the indices of refraction of the CPC and LED dice to efficiently optically couple the LED triad to the CPC.

The cylindrical reflector 16 is a hollow cylindrical sleeve that surrounds the CPC 14. The cylindrical sleeve has a reflective inner surface. The CPC 14 reflects light that intersects the CPC boundary at an angle greater than or equal to the total internal reflection angle (TIR) of the CPC. The reflective inner surface of the cylindrical sleeve 16 reflects light that intersects the CPC 14 at an angle lower than the TIR angle of the CPC 14. It has been found that the CPC 14 more efficiently mixes the light from the three LED die 20, 22 and 24 so that the light emitted by the light source 10 appears to be from a single point source as opposed to three different die. Moreover, the CPC 14 in combination with the cylindrical reflector 16 is 20% more efficient than conventional LED light sources, providing a much brighter light for a given amount of power. In particular the LED light source 10 has a light output that is greater than or equal to 3 mW.

In another embodiment of the present invention, as shown in FIGS. 2 and 3, the inner reflective surface of the cylindrical sleeve 16 is tapered at the end 36 of the sleeve surrounding the entrance surface 32 of the CPC 14. More particularly, approximately one quarter to one third of the reflective inner surface of the cylindrical sleeve 16 is tapered so that the tapered portion 36 of the inner surface is a truncated cone 36. The angle of the tapered surface 36 is within the range of 32°-42° and is preferably approximately 37°. The tapered inner reflective surface minimizes the number of bounces within the CPC after the light is directed back into the CPC by the tapered reflective surface 36 of the cylindrical reflector 16. It has been found that this increases the light efficiency of the LED light source to create even brighter light.

Many modifications and variations of the present invention are possible in light of the above teachings. Thus it is to be understood that, within the scope of the appended claims, the invention may be practiced otherwise than as described hereinabove.

What is claimed and desired to be secured by Letters Patent is:

1. A full spectrum LED light source comprising:
a LED triad having a red LED die, a green LED die, and a blue LED die;
a total internal reflection compound parabolic concentrator (CPC) having a first surface for receiving light from the LED triad and a second surface through which light exits; and
a cylindrical sleeve surrounding the CPC, the cylindrical sleeve having a reflective inner surface to reflect light escaping from the CPC back into the CPC.

2. The full spectrum LED light source as recited in claim 1 wherein the reflective inner surface of the sleeve is tapered at the end of the sleeve surrounding the first surface of the CPC.

3. A full spectrum LED light source as recited in claim 1 wherein the center wavelength of the green LED is approximately 535 nm, the center wavelength of the red LED is approximately 625 nm, and the center wavelength of the blue LED is approximately 445 nm.

4. A full spectrum LED light source as recited in claim 1 wherein the first surface of the CPC has a radius R that is 1.8 mm to 2.4 mm and the CPC has an exit angle θₘₐₓ that is 35° to 55°.

5. A full spectrum LED light source as recited in claim 4 wherein the radius R of the first surface of the CPC is 2.0 mm and the exit angle θₘₐₓ of the CPC is 45°.

6. A full spectrum LED light source as recited in claim 1 wherein the first surface of the CPC has a radius R that is 1.8 mm to 2.4 mm and the CPC has an exit angle θₘₐₓ that is 18° to 22°.

7. A full spectrum LED light source as recited in claim 6 wherein the radius R of the first surface of the CPC is 2.0 mm, the exit angle θₘₐₓ of the CPC is 20°.

8. A full spectrum LED light source as recited in claim 1 wherein the LED triad is mounted centrally on a substrate, each of the LED die has at least one wirebond on a top surface of the LED die and wherein each of said wirebonds is connected to the substrate so that it extends radially away from the center of the LED triad.

9. A full spectrum LED light source as recited in claim 8 wherein each of the LED die is connected to a heat sink trace on the substrate wherein the heat sink trace extends radially away from the center of the LED triad.

10. A full spectrum LED light source as recited as claim 3 wherein the first surface of the CPC is concave and the LED triad is mounted in the concave first surface of the CPC with a silicone gel having an index of refraction that matches the index of refraction of the CPC or that is between the indices of refraction of the CPC and the LED dice.

11. A full spectrum LED light source as recited in claim 2 wherein the center wavelength of the green LED is approximately 535 nm, the center wavelength of the red LED is approximately 625 nm, and the center wavelength of the blue LED is approximately 445 nm.

12. A full spectrum LED light source comprising:
a total internal reflection compound parabolic concentrator (CPC) having a concave first surface for receiving light and a second surface through which light exits;
a cylindrical sleeve surrounding the CPC, the cylindrical sleeve having a reflective inner surface to reflect light escaping from the CPC back into the CPC; and
a LED triad having a red LED die, a green LED die, and a blue LED die wherein the LED triad is mounted in the concave entrance surface of the CPC such that the CPC captures light emitted from the sides of the LED triad and provides a light output that is greater than or equal to 3 mW.

13. A full spectrum LED light source as recited in claim 12 wherein the LED triad is secured to the CPC in the concave entrance surface within the CPC with a silicone gel having an index of refraction that matches the index of refraction of the CPC or that is between the indices of refraction of the CPC and the LED dice.

14. A full spectrum LED light source as recited in claim 12 wherein the LED triad is mounted centrally on a substrate and the CPC and cylindrical sleeve abut the substrate and surround the LED triad.

15. A full spectrum LED light source as recited in claim 12 wherein the LED triad is mounted centrally on a substrate, each of the LED die has at least one wirebond on a top surface of the LED die and wherein each of said wirebonds is connected to the substrate so that it extends radially away from the center of the LED triad.

16. A full spectrum LED light source as recited in claim 15 wherein each of the LED die is connected to a heat sink trace on the substrate wherein the heat sink trace extends radially away from the center of the LED triad.

17. A full spectrum LED light source as recited in claim 12 wherein the center wavelength of the green LED is approximately 535 nm, the center wavelength of the red LED is approximately 625 nm, and the center wavelength of the blue LED is approximately 445 nm.

18. A full spectrum LED light source as recited in claim 12 wherein the first surface of the CPC has a radius R that is 1.8 mm to 2.4 mm and the CPC has an exit angle θₘₐₓ that is 35° to 55°.

19. A full spectrum LED light source as recited in claim 18 wherein the radius R of the first surface of the CPC is 2.0 mm and the exit angle θₘₐₓ of the CPC is 45°.

20. A full spectrum LED light source as recited in claim 12 wherein the first surface of the CPC has a radius R that is 1.8 mm to 2.4 mm and the CPC has an exit angle θₘₐₓ that is 18° to 22°.

21. A full spectrum LED light source as recited in claim 20 wherein the radius R of the first surface of the CPC is 2.0 mm, the exit angle θₘₐₓ of the CPC is 20°.

22. A full spectrum LED light source comprising:
a total internal reflection compound parabolic concentrator (CPC) having a concave first surface for receiving light and a second surface through which light exits;
a cylindrical sleeve surrounding the CPC, the cylindrical sleeve having a reflective inner surface that is tapered at the end of the sleeve surrounding the first surface of the CPC to reflect light escaping from the CPC back into the CPC;
a LED triad having a red LED die, a green LED die, and a blue LED die wherein the LED triad is mounted in the concave entrance surface of the CPC such that the CPC captures light emitted from the sides of the LED triad and provides a light output that is greater than or equal to 3 mW.

23. A full spectrum LED light source as recited in claim 22 wherein the LED triad is secured to the CPC in the concave entrance surface with a silicone gel having an index of refraction that matches the index of refraction of the CPC or that is between the indices of refraction of the CPC and the LED dice.

24. A full spectrum LED light source as recited in claim 22 wherein the LED triad is mounted centrally on a substrate and the CPC and cylindrical sleeve abut the substrate and surround the LED triad.

25. A full spectrum LED light source as recited in claim 22 wherein the LED triad is mounted centrally on a substrate, each of the LED die has at least one wirebond on a top surface of the LED die and wherein each of said wirebonds is connected to the substrate so that it extends radially away from the center of the LED triad.

26. A full spectrum LED light source as recited in claim 25 wherein each of the LED die is connected to a heat sink trace on the substrate wherein the heat sink trace extends radially away from the center of the LED triad.

27. A full spectrum LED light source as recited in claim 22 wherein the center wavelength of the green LED is approximately 535 nm, the center wavelength of the red LED is approximately 625 nm, and the center wavelength of the blue LED is approximately 445 nm.

28. A full spectrum LED light source as recited in claim 22 wherein the first surface of the CPC has a radius R that is 1.8 mm to 2.4 mm and the CPC has an exit angle θₘₐₓ that is 35° to 55°.

29. A full spectrum LED light source as recited in claim 28 wherein the radius R of the first surface of the CPC is 2.0 mm and the exit angle θₘₐₓ of the CPC is 45°.

30. A full spectrum LED light source as recited in claim 22 wherein the first surface of the CPC has a radius R that is 1.8 mm to 2.4 mm and the CPC has an exit angle θₘₐₓ that is 18° to 22°.

31. A full spectrum LED light source as recited in claim 30 wherein the radius R of the first surface of the CPC is 2.0 mm, the exit angle θₘₐₓ of the CPC is 20°.

32. A full spectrum LED light source comprising:
a total internal reflection compound parabolic concentrator (CPC) having a concave first surface for receiving light and a second surface through which light exits;
a LED triad having a red LED die, a green LED die, and a blue LED die wherein the LED triad is mounted in the concave entrance surface of the CPC such that the CPC captures light emitted from the sides of the LED triad and provides a light output that is greater than or equal to 3 mW.

33. A full spectrum LED light source as recited in claim 32 wherein the LED triad is secured to the CPC in the concave entrance surface with a silicone gel having an index of refraction that matches the index of refraction of the CPC or that is between the indices of refraction of the CPC and the LED dice.

34. A full spectrum LED light source as recited in claim 32 wherein the LED triad is mounted centrally on a substrate, each of the LED die has at least one wirebond on a top surface of the LED die and wherein each of said wirebonds is connected to the substrate so that it extends radially away from the center of the LED triad.

35. A full spectrum LED light source as recited in claim 34 wherein each of the LED die is connected to a heat sink trace on the substrate wherein the heat sink trace extends radially away from the center of the LED triad.

36. A full spectrum LED light source as recited in claim 32 wherein the center wavelength of the green LED is approximately 535 nm, the center wavelength of the red LED is approximately 625 nm, and the center wavelength of the blue LED is approximately 445 nm.

37. A full spectrum LED light source as recited in claim 32 wherein the first surface of the CPC has a radius R that is 1.8 mm to 2.4 mm and the CPC has an exit angle θₘₐₓ that is 35° to 55°.

38. A full spectrum LED light source as recited in claim 37 wherein the radius R of the first surface of the CPC is 2.0 mm and the exit angle θₘₐₓ of the CPC is 45°.

39. A full spectrum LED light source as recited in claim 32 wherein the first surface of the CPC has a radius R that is 1.8 mm to 2.4 mm and the CPC has an exit angle θₘₐₓ that is 18° to 22°.

40. A full spectrum LED light source as recited in claim 39 wherein the radius R of the first surface of the CPC is 2.0 mm, the exit angle θₘₐₓ of the CPC is 20°.
